(19) United States
(12) Patent Application Publication
(10) Pub. No.: US 2020/0033972 A1
(43) Pub. Date: Jan. 30, 2020

(54) IN-CELL TOUCH PANEL

(71) Applicant: Wuhan China Star Optoelectronics Technology Co., Ltd., Wuhan, Hubei (CN)

(72) Inventors: Yao-li HUANG, Shenzhen, Guangdong (CN); Hongsen ZHANG, Shenzhen, Guangdong (CN)

(21) Appl. No.: 15/735,492

(22) PCT Filed: Nov. 6, 2017
(86) PCT No.: PCT/CN2017/109581

§ 371 Date: Dec. 11, 2017

(30) Foreign Application Priority Data
Sep. 27, 2017 (CN) 201710889843.5

(51) Int. Cl. G06F 3/041; H01L 27/12; H01L 23/498; G02F 1/1333; G02F 1/1345; G02F 1/1362; G09G 3/36

(52) U.S. Cl. CPC G06F 3/0412; H01L 27/124; H01L 23/49838; G02F 1/13338; G02F 1/1368; G02F 1/136286; G06F 3/04164; G09G 3/3648; H01L 23/4985; G02F 1/13452

(57) ABSTRACT

An In-cell touch panel is provided in the present application, including an array substrate and a chip on film, wherein the array substrate includes a display area and a non-display area, the non-display area includes an outer lead bonding region for receiving an external signal by jointing to the chip on film, a plurality of transmission pins is disposed on the outer lead bonding region, a connection line is disposed on the non-display area to connected to the transmission pins, the connection line is used for transmitting the external signal to the display area; and an integrated circuit is disposed on the chip on film for realizing the functions of touch and display, to increase the screen-to-body ratio of the display device, and improve the user experience.

### RELATED APPLICATIONS

The present application is a National Phase of International Application Number PCT/CN2017/109581, filed Nov. 6, 2017, and claims the priority of China Application No. 201710889843.5, filed Sep. 27, 2017.

### FIELD OF THE DISCLOSURE

The disclosure relates to a display technical field, and more particularly to an In-cell touch panel.

### BACKGROUND

With the continuous development of the market, liquid crystal display technology and touch technology continue to improve, and users have put more stringent requirements on designs of mobile phones and tablet computers. The screen-to-body ratio is the ratio of the area of the display area of the display device to the area of the entire surface, the screen-to-body ratio has a greater impact on the overall appearance of the display device, the higher screen-to-body ratio makes the stronger overall sense of the display device, and more attractive to the users.

In-cell touch technology also began to more and more apply to mobile phones and other display products by relying on good touch effects and lower thickness. For the liquid crystal display, LCD, the touch circuit structure can be integrated on the side of the Thin Film Transistor, TFT substrate, or on the side of the Color Filter, CF substrate. The method for improving the screen-to-body ratio of the liquid crystal display with the In-cell touch circuit generally narrows the size of the upper, left and right borders of the display device, if the design of the complete glass cover is adopted, the three-sided borderless visual effect on three the sides. The current narrow border design has basically compressed the peripheral circuits of the left, right, and top borders to the extreme (such as the narrowest border has been compressed to 0, 3 mm).

In the conventional technology, the bottom border of the display device generally adopts a design scheme of an integrity circuit, IC combined with a flexible print circuit board, FPC. Although the effect of reducing the size of the border can be achieved by compressing the related traces and the size of the related circuit function unit, the reduction of the size of the lower border is limited and the size of the lower border is still larger, resulting in a lower screen-to-body ratio, and affecting the user experience.

### SUMMARY

The technical problem to be solved by the present application is to provide an In-cell touch panel, to solve the problems of the relatively larger border size, the lower screen-to-body ratio, and the poor user experience of the In-cell touch panel in the conventional technology.

In order to solve the above technical problem, the present application provides an In-cell touch panel, including an array substrate and a chip on film, wherein the array substrate includes a display area and a non-display area, the non-display area includes an outer lead bonding region for receiving an external signal by jointing to the chip on film, a plurality of transmission pins is disposed on the outer lead bonding region, a connection line is disposed on the non-display area to connected to the transmission pins, the connection line is used for transmitting the external signal to the display area; and an integrated circuit is disposed on the chip on film for realizing the functions of touch and display.

Wherein the chip on film includes a fixed end and a carrier portion interconnected as one, the fixed end is jointed to a chip on film bonding area disposed on the array substrate, the carrier portion is provided with the integrated circuit for realizing the functions of touch and display.

Wherein the fixed end includes first pins and second pins staggered arrangement, the first pins and the second pins are electrically connected to the connection lines through transmission pins on the chip on film bonding area.

Wherein the first pins transmit scan signals or data signals, and the second pins transmit touch signals.

Wherein the connection line includes a first connection line, one end of the first connection lines is electrically connected to the first pin and the other end of the first connection line is electrically connected to the gate lines or the data lines.

Wherein the connection line includes a second connection line, one end of the second connection line is electrically connected to the second pin, and the other end of the second connection line is electrically connected to the touch electrode.

Wherein the array substrate includes two conductive layers insulated from each other, the first connection line and the second connection line are respectively disposed on the two conductive layers.

Wherein the gate lines and the data lines intersect to form a plurality of sub-pixel regions, a thin film transistor and a pixel electrode are disposed in each of the sub-pixel regions, the first connection line is electrically connected to the data line, and inputting a display signal to the pixel electrode when the thin film transistor is turned on.

Wherein the integrated circuit integrates functions of touch and display, the touch signals and the display signals generated by the integrated circuit are transmitted from the chip on film to the array substrate through the first pins and the second pins, respectively.

Wherein the touch electrode in the display area is electrically connected to the second connection line through a via hole.

Wherein the first pins and the second pins in at least a part of the fixed ends are staggered arrangement, and the first pins and the second pins are electrically connected to the connection line through the transmission pins on the chip on film bonding area.

Wherein the first pins transmit scan signals or data signals, and the second pins transmit touch signals.

Wherein among the plurality of transmission pins on the chip on film bonding area, each of the transmission pins for receiving the touch signals are disposed between two adjacent transmission pins for receiving the scan signals or the data signals.

Wherein among the plurality of transmission pins on the chip on film bonding area, each of the transmission pins for receiving the scan signals or the data signals is disposed between two adjacent transmission pins for receiving the touch signal.

The beneficial effects of the present application are as follows: An integrated circuit packaged on the chip on film, COF integrates display and touch functions. The integrated circuit is electrically connected to the display area through a connection line to achieve display and touch functions. The integrated circuit does not occupy the size of the non-display area, and the size of the non-display area occupied by the chip on film is smaller, thereby reducing the size of the non-display area, increase the screen-to-body ratio of the display device, and improve the user experience.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a schematic diagram of an In-cell touch panel provided in an embodiment of the present application:

FIG. 2 is a schematic diagram of an array substrate according to an embodiment of the present application;

FIG. 3 is an enlarged schematic diagram of a part of the In-cell touch panel according to an embodiment of the present application;

FIG. 4 is a schematic diagram of a backside of the chip on film provided in the embodiment of the present application;

FIG. 5 is a schematic side view diagram of the In-cell touch panel provided in the embodiment of the present application; and

FIG. 6 is a schematic diagram of a touch electrode of the In-cell touch panel according to an embodiment of the present application.

### DETAILED DESCRIPTION OF PREFERRED EMBODIMENTS

The technical solutions in the embodiments of the present application are clearly and completely described below with reference to the accompanying drawings in the embodiments of the present application. Apparently, the described embodiments are merely some but not all of the embodiments of the present application. All other embodiments obtained by a person of ordinary skill in the art based on the embodiments of the present application without creative efforts shall fall in the protection scope of this application.

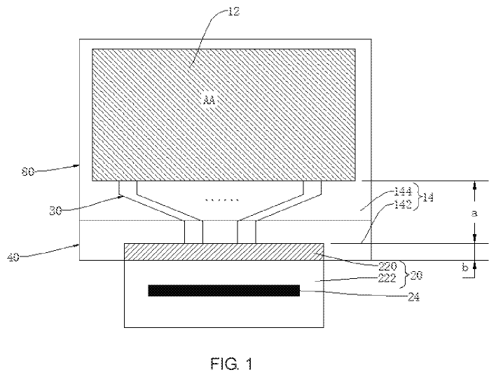

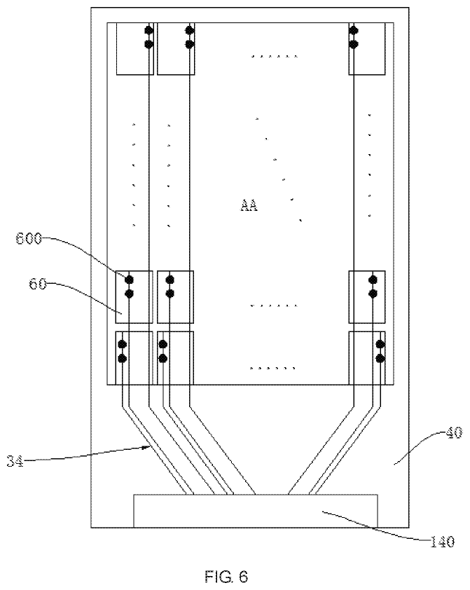

Referring to FIGS. 1 to 5, the In-cell touch panel provided by the embodiment of the present application has display and touch functions, wherein the display function is achieved by a display panel, such as a liquid crystal display panel or an organic light-emitting diode display panel, the touch function is achieved by the touch electrodes 60 embedded in the display panel. In this embodiment, the In-cell touch panel includes a color filter substrate 80, an array substrate 40 and a liquid crystal layer 50. The color filter substrate 80 is disposed opposite to the array substrate 40. The liquid crystal layer 50 is disposed between the color filter substrate 80 and the array substrate 40 thereby forming a liquid crystal cell. The connection line controls the deflection of the liquid crystal molecules in the liquid crystal layer 50 by controlling the voltage difference between the color filter substrate 80 and the array substrate 40 to control the image to be displayed. In an embodiment, the touch electrodes 60 are embedded in the display panel. Specifically, the touch electrodes 60 is located on the array substrate 40, and the touch electrodes 60 is located between the liquid crystal layer 50 and the array substrate 40. The touch electrodes 60 is used to convert the touch signal applied by the user's finger to the In-cell touch panel into an electrical signal and transmit the signal to an integrated circuit 24 for processing and analysis. In an implementation manner, the touch electrodes 60 are a patterned transparent conductive film, such as an Indium Tin Oxide, ITO film.

In this embodiment, the In-cell touch panel further includes a chip on film 20, the integrated circuit 24 is disposed on the chip on film 20, the chip on film 20 itself can be bent, the integrated circuit 24 is electrically connected to the In-cell touch panel and a system board by the two ends of the chip on film 20. In an implementation manner, the integrated circuit 24 integrates the functions of display and touch. Specifically, the integrated circuit 24 may be a TDDI IC, that is, the touch & display driver integrity IC.

In this embodiment, the array substrate 40 includes a display area 12 and a non-display area 14. The non-display area 14 is located at an edge of the display area 12, Specifically, the edge between the edge of the display area 12 and the edge of the array substrate 40 is the non-display area 14. Since the display area 12 is located at the center of the array substrate 40, the non-display area 14 is a frame area surrounding the display area 12. Further, the color filter substrate 80 and the array substrate 40 are laminating disposed, the size of the color filter substrate 80 is smaller than the size of the array substrate 40, an outer lead bonding, OLB region 142 is formed in a portion not covered by the vertical projection of the color filter substrate 80 in the array substrate 40, the non-display area 14 in this embodiment of the present application may be a lower bounding area, that is, the non-display area is located in a side of the outer lead bonding region 142 is located. In this embodiment, the non-display area 14 includes the outer lead bonding region 142 and a trace area 144. The trace area 144 is an area between the vertical projection of the edge of the color filter substrate 80 adjacent to the outer lead bonding region 142 in the array substrate 40 and the edge of the display area 12.

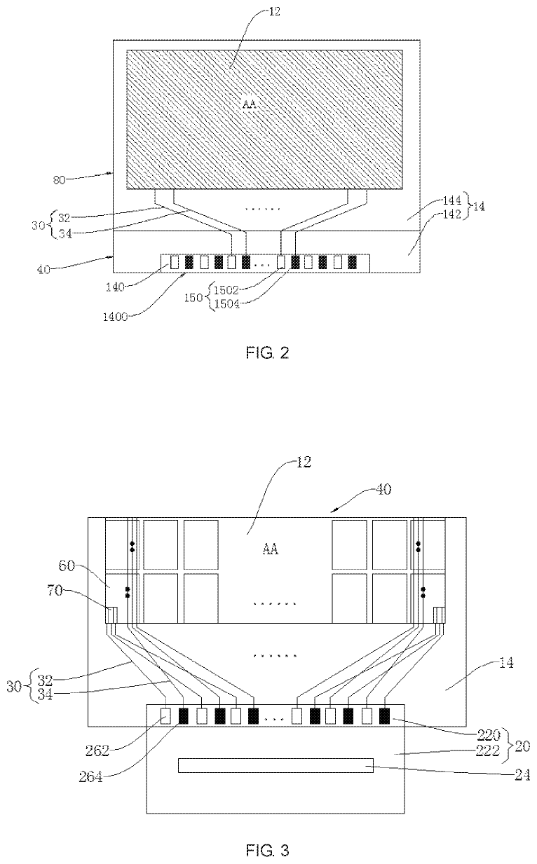

In this embodiment, the display area 12 is provided with a gate line and a data line for controlling image display. Specifically, the display area 12 is further provided with a thin film transistor and a pixel electrode connected to a drain or a source of the thin film transistor. The data line is connected to the drain or the source of the thin film transistor, a scan line is connected to a gate of the thin film transistor. Specifically, referring to FIG. 2, the non-display area 14 is provided with a chip on film bonding area 140. The chip on film bonding area 140 receives an external signal by jointing to the chip on film 20. The chip on film 20 is fixed to the chip on film bonding area 140, therefor to be fixed to the array substrate 40. Specifically, referring to FIG. 2, in this embodiment, a plurality of transmission pins 150 are disposed on the chip on film bonding area 140, a connection lines 30 connected to the transmission pins 150 is further disposed on the non-display region 14, the connection lines 30 is used for transmitting the external signal to the display area 12. In one embodiment, the transmission pins 150 are sequentially arranged along the length direction of the chip on film bonding area 140.

In the present embodiment, the chip on film 20 includes a fixed end 220 and a carrier portion 222 interconnected as one, the fixed end 220 and a carrier portion 222 interconnected. The fixed end 220 is jointed to the non-display area 14. The carrier portion 222 is located outside the array substrate 40, the carrier portion 222 is configured to carry the integrated circuit 24, the integrated circuit 24 is electrically connected to the gate line or the data line and the touch electrodes 60 through the chip on film 20. In an embodiment, the fixed end 220 is bonded to the chip on film bonding area 140 through an anisotropic conductive film, ACF. In other embodiments, the fixed end 220 may also be fixed to the chip on film bonding area 140 by welding. In this embodiment, the chip on film bonding area 140 is located in the outer lead bonding region 142, the size of the outer lead bonding region 142 is affected by the size of the chip on film bonding area 140. The smaller of the size of the chip on film bonding area 140, the smaller of the outer lead bonding region 142 is, that is, the smaller the size of the non-display area 14 is.

The integrated circuit 24 packaged on the chip on film 20 is integrated the functions of display and touch. The integrated circuit 24 is electrically connected to the gate lines or the data lines through the gate lines or the data lines and the touch electrodes 60 to achieve the functions of display and touch, the fixed end 220 of the chip on film 20 is jointed to the non-display area 14 (the outer lead bonding region 142), the integrated circuit 24 is located on the carrier portion 222 outside the array substrate 40, compared with the conventional technology of disposing the regional bonding integrated circuit 24 and the flexible circuit board in the non-display area 14, the In-cell touch panel provided in this embodiment of the present application only has a fixed end 220 (the chip on film bonding area 140 occupies a width b as shown in FIG. 1) and a region for connecting the fixed end 220 and the display area 12 (the width of the connection lines 30 occupies the width a as shown in FIG. 1) occupy the size of the non-display area 14, the integrated circuit 24 does not occupy the size of the non-display area 14, and the connection traces of the integrated circuit 24 and the chip on film 20 are not occupied the size of the non-display area 14, so as to reduce the size of the non-display area 14 (the outer lead bonding region 142), increase the screen-to-body ratio of the display device, and improve the user experience.

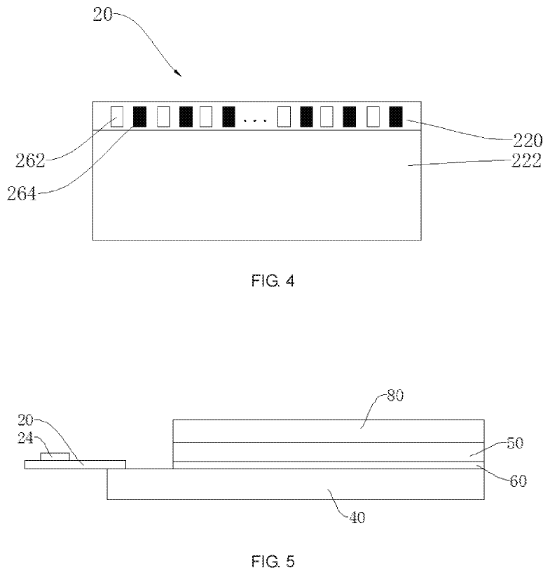

In this embodiment, the chip on film 20 fixed on the chip on film bonding area 140 is electrically connected to the gate lines or the data lines and the touch electrodes 60 through the connection lines 30. Specifically referring to FIG. 4, the fixed end 220 of the chip on film 20 includes first pins 262 and second pins 264 sequentially staggered arrangement. The first pins 262 and the second pins 264 are electrically connected to the connection lines 30 through transmission pins 150 on the chip on film bonding area 140, wherein the first pins 262 transmit scan signals or data signals, and the second pins 264 transmit touch signals. In this embodiment, the first pins 262 and the second pins 264 are electrically connected to the connection lines 30 through the transmission pins 150 on the chip on film bonding area 140. Specifically, the transmission pins 150 include first transmission pins 1502 and second transmission pins 1504 sequentially staggered arrangement, the first transmission pins 1502 are electrically connected to the gate lines or the data lines through the connection lines 30, the second pass pins 1504 are electrically connected to the touch electrodes 60 through the connection lines 30. After the chip on film 20 is bound to the chip on film bonding area 140, the first pins 262 are correspondingly connected to the first transmission pins 1502, the second pins 264 are correspondingly connected to the second transmission pins 1504, so that the first pins 262 are electrically connected to the gate lines or the data lines, and the second pins 264 are electrically connected to the touch electrodes 60. In one embodiment, the connection lines 30 connection lines includes first connection lines 32 and second connection lines 34. One end of the first connection lines 32 are electrically connected to the first pin 262 and the other end of the first connection lines 32 are electrically connected to the gate lines or the data lines. One end of the second connection lines 34 are electrically connected to the second pin 264, and the other end of the second connection lines 34 are electrically connected to the touch electrodes 60. Specifically, the connection lines 30 are metal lines formed by a patterned metal layer. In an embodiment, the connection lines 30 may be Mo, Mo/Al/Mo, Ti/Al/Ti, or Cu.

In this embodiment, the first pins 262 and the second pins 264 in at least a part of the fixed end 220 are staggered arrangement, the first pins 262 and the second pins 264 are electrically connected to the connection lines 30 through the transmission pins 150 on the chip on film bonding area 140, wherein the first pins 262 transmit the scan signals or a data signals, and the second pins 264 transmit the touch signal.

In this embodiment, among the plurality of transmission pins 150 on the chip on film bonding area 140, each of the transmission pins 150 for receiving the touch signals are disposed between two adjacent transmission pins 150 for receiving the scan signals or the data signals; or each of the transmission pins 150 for receiving the scan signals or the data signals is disposed between two adjacent transmission pins 150 for receiving the touch signal.

Specifically referring to FIG. 3, the chip on film bonding area 140 is located closed to central of the non-display area 14, that is the chip on film 20 is fixed at the center of the non-display area 14, since a horizontal size of the chip on film 20 is smaller than a horizontal size of the display area 12, the connection lines 30 connected to the transmission pins 150 needs to be bent. In one embodiment, the connection lines 30 include first connection lines 32 and second connection lines 34. The first connection lines 32 are electrically connected to the first transmitting pins 1502 and the gate lines or the data lines, the second connection lines 34 are electrically connected to the second transmission pins 1504 and the touch electrodes 60. If a horizontal distance between the first pins 262 and the gate lines or the data lines is too large, in order to ensure that the trace area 144 can contain all the first connection lines 32 and the first connection lines 32 are not easily broken, it is necessary to increase a vertical distance between the first pins 262 and the gate lines or the data lines, to reduce the bending width of the first connection lines 32, resulting in the size of the trace area 144 is increased. If a horizontal distance between the second pins 264 and the touch electrodes 60 is too large, in order to ensure that the trace area 144 can contain all of the second connection lines 34 and the second connection lines 34 are not easily broken, it is necessary to increase a vertical distance between the second pins 264 and the touch electrodes 60, to reduce the bending width of the second connection lines 34, resulting in the size of the trace area 144 is increased. In this embodiment, the first transmission pins 1502 and the second transmission pins 1504 are staggered arrangement, the corresponding first pins 262 and the second pins 264 are staggered arrangement, to reduce the horizontal distance between the first transmission pins 1502 and the gate lines or the data lines and the horizontal distance between the second transmission pins 1504 and the touch electrodes 60, and to correspondingly reduce the vertical distance between the first pins 262 and the gate lines or the data lines and the vertical distance between the second pins 264 and the touch electrodes 60, thereby reducing the size of the trace area 144, that is, to reduce the size of the non-display area 14, and the screen-to-body ratio is increased.

In this embodiment, the array substrate 40 includes two conductive layers insulated from each other, the first connection lines 32 and the second connection lines 34 are respectively disposed on the two conductive layers, wherein the conductive layer is a metal layer. Specifically, the gate lines or the data lines are located at a different layer from the touch electrodes 60, the first connection lines 32 are electrically connected to the gate lines or the data lines and the chip on film 20 to achieve the function of display image. The second connection lines 34 are electrically connected to the touch electrodes 60 and the chip on film 20 to achieve a touch function. The first connection lines 32 and the second connection lines 34 are insulated from each other, so that the image display function and the touch function are independent to each other. In one embodiment, the conductive layers include a first metal layer and a second metal layer. The first connection lines 32 are formed by patterning the first metal layer through etching or the like, and the second connection lines 34 are formed by patterning the second metal layer through etching or the like, the first metal layer and the second metal layer are both metal layers, the first connection lines 32 and the second connection lines 34 are metal lines formed by patterning the first metal layer and the second metal layer. In an embodiment, the connection lines 30 may be Mo, Mo/Al/Mo, Ti/Al/Ti, Cu or Ag. When the first connection lines 32 and the second connection lines 34 are Ag, the resistance of the Ag lines are small, which facilitates the debugging of the integrated circuit 24.

In the present embodiment, the chip on film bonding area 140 includes a first edge 1400 away from the display region 12, the first edge 1400 is flush with the edge of the array substrate 40. Specifically, the chip on film bonding area 140 is rectangular, the first edge 1400 is a long side of the rectangular, the first edge 1400 is flush with the edge of the outer lead bonding region 142 away from the trace area 144, to make no gap is between the chip on film bonding area 140 and the edge of the array substrate 40, so as to maximize the size of the smaller non-display region 14, increase the screen-to-body ratio of the display device, and improve the user experience.

In this embodiment, the gate lines and the data lines are intersected to form a plurality of sub-pixel regions, each of the sub-pixel regions is provided with a thin film transistor and a pixel electrode, the gate lines or data lines include data lines, the first connection lines 32 are connected to the data lines, so as to be electrically connected to the pixel electrode through the thin film transistor. In an implementation manner, the thin film transistor includes a source electrode, a drain electrode and a gate electrode. The gate electrode is electrically connected to the scan line to be electrically connected to the scan connection line. The scan connection line sends a scan signal to control the on-off state of the source electrode and the drain electrode, the drain electrode is electrically connected to the first connection line 32, the source electrode is electrically connected to the pixel electrode. When the drain electrode is connected to the source electrode, the first connection lines 32 transmit a data signal to control the pixel voltage of the pixel electrode.

In this embodiment, the integrated circuit 24 integrates the touch and display functions. The touch signals and the display signals generated by the integrated circuit 24 are respectively transmitted from the chip on film 20 to the array substrate 40 through the first pins 262 and the second pins 264.

In conjunction with FIG. 6, the touch electrodes 60 are electrically connected to the second connection lines 34 through the via holes 600. The fabrication of the connection way of the via holes 600 is simple, low processing costs, good electrical connection effect.

The integrated circuit 24 packaged on the chip on film 20 integrates display and touch functions. The integrated circuit 24 is electrically connected to the gate lines or the data lines and the touch electrodes 60 to achieve the display and touch functions. The fixed end 220 of the chip on film 20 is jointed to the non-display area 14, the integrated circuit 24 is located on the carrier portion 222 outside the array substrate 40, compared with the conventional technology of disposing the regional bonding integrated circuit 24 and the flexible circuit board in the non-display area 14, the integrated circuit 24 does not occupy the size of the non-display area 14, so as to reduce the size of the non-display area 14, increase the screen-to-body ratio of the display device, and improve the user experience.

The integrated circuit 24 packaged on the chip on film 20 integrates display and touch functions. The integrated circuit 24 is electrically connected to the gate lines or the data lines through the gate lines or the data lines and the touch electrodes 60 to achieve the display and touch functions, the fixed end 220 of the chip on film 20 is jointed to the non-display area 14 (the outer lead bonding region 142), the integrated circuit 24 is located on the carrier portion 222 outside the array substrate 40, compared with the conventional technology of disposing the regional bonding integrated circuit 24 and the flexible circuit board in the non-display area 14, the In-cell touch panel provided in this embodiment of the present application only has a fixed end 220 (the chip on film bonding area 140 occupies a width b as shown in FIG. 1) and a region for connecting the fixed end 220 and the display area 12 (the width of the connection lines 30 occupies the width a as shown in FIG. 1) occupy the size of the non-display area 14, the integrated circuit 24 does not occupy the size of the non-display area 14, and the connection traces of the integrated circuit 24 and the chip on film 20 are not occupied the size of the non-display area 14, so as to reduce the size of the non-display area 14 (the outer lead bonding region 142), increase the screen-to-body ratio of the display device, and improve the user experience.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. An In-cell touch panel, comprising:
an array substrate and a chip on film, wherein the array substrate comprises a display area and a non-display area, the non-display area comprises an outer lead bonding region for receiving an external signal by jointing to the chip on film, a plurality of transmission pins is disposed on the outer lead bonding region, a connection line is disposed on the non-display area to connected to the transmission pins, the connection line is used for transmitting the external signal to the display area; and
an integrated circuit is disposed on the chip on film for realizing the functions of touch and display.

2. The In-cell touch panel according to claim 1, wherein the chip on film comprises a fixed end and a carrier portion interconnected as one, the fixed end is jointed to a chip on film bonding area disposed on the array substrate, the carrier portion is provided with the integrated circuit for realizing the functions of touch and display.

3. The In-cell touch panel according to claim 2, wherein the fixed end comprises first pins and second pins staggered arrangement, the first pins and the second pins are electrically connected to the connection lines through transmission pins on the chip on film bonding area.

4. The In-cell touch panel according to claim 3, wherein the first pins transmit scan signals or data signals, and the second pins transmit touch signals.

5. The In-cell touch panel according to claim 4, wherein the connection line comprises a first connection line, one end of the first connection lines is electrically connected to the first pin and the other end of the first connection line is electrically connected to the gate lines or the data lines.

6. The In-cell touch panel according to claim 5, wherein the connection line comprises a second connection line, one end of the second connection line is electrically connected to the second pin, and the other end of the second connection line is electrically connected to the touch electrode.

7. The In-cell touch panel according to claim 6, wherein the array substrate comprises two conductive layers insulated from each other, the first connection line and the second connection line are respectively disposed on the two conductive layers.

8. The In-cell touch panel according to claim 7, wherein the gate lines and the data lines intersect to form a plurality of sub-pixel regions, a thin film transistor and a pixel electrode are disposed in each of the sub-pixel regions, the first connection line is electrically connected to the data line, and inputting a display signal to the pixel electrode when the thin film transistor is turned on.

9. The In-cell touch panel according to claim 4, wherein the integrated circuit integrates functions of touch and display, the touch signals and the display signals generated by the integrated circuit are transmitted from the chip on film to the array substrate through the first pins and the second pins, respectively.

10. The In-cell touch panel according to claim 6, wherein the touch electrode in the display area is electrically connected to the second connection line through a via hole.

11. The In-cell touch panel according to claim 4, wherein the first pins and the second pins in at least a part of the fixed ends are staggered arrangement, and the first pins and the second pins are electrically connected to the connection line through the transmission pins on the chip on film bonding area.

12. The In-cell touch panel according to claim 11, wherein the first pins transmit scan signals or data signals, and the second pins transmit touch signals.

13. The In-cell touch panel according to claim 1, wherein among the plurality of transmission pins on the chip on film bonding area, each of the transmission pins for receiving the touch signals are disposed between two adjacent transmission pins for receiving the scan signals or the data signals.

14. The In-cell touch panel according to claim 1, wherein among the plurality of transmission pins on the chip on film bonding area, each of the transmission pins for receiving the scan signals or the data signals is disposed between two adjacent transmission pins for receiving the touch signal.
